(19) United States
(12) Patent Application Publication
(10) Pub. No.: US 2005/0204217 A1
(43) Pub. Date: Sep. 15, 2005

(54) Identical core testing using dedicated compare and mask circuitry

(76) Inventors: Lee D. Whetsel, Parker, TX (US); Alan Hales, Richardson, TX (US)

Correspondence Address: TEXAS INSTRUMENTS INCORPORATED, P O BOX 655474, M/S 3999, DALLAS, TX, 75265, US

(21) Appl. No.: 11/051,696

(22) Filed: Feb. 4, 2005

Related U.S. Application Data
(60) Provisional application No. 60/542,410, filed on Feb. 6, 2004.
(60) Provisional application No. 60/542,810, filed on Feb. 6, 2004.

(51) Int. Cl. G01R 31/28

(52) U.S. Cl. 714/724

(57) ABSTRACT

Today large system-on-chips (SOC) are designed using predefined circuit functions commonly referred to as cores. In some cases, multiple instances of the same core may be implemented within an SOC to achieve greater functional performance of the SOC. Having multiple cores of the same type in an SOC lends itself to parallel testing of the cores. This disclosure describes an improved core DFT architecture that facilitates parallel testing of same type cores within an SOC.

### CROSS REFERENCE TO RELATED APPLICATIONS

This application is related to the following US patents/applications which are incorporated herein by reference.
U.S. Pat. No. 6,560,734 to Whetsel, issued May 6, 2003, IC With Addressable Test Port.
U.S. Pat. No. 6,717,429 to Whetsel, issued Apr. 6, 2004.
U.S. patent application Ser. No. 10/301,898 to Whetsel, et al., filed Nov. 22, 2002, Scan Testing System, Method, and Apparatus.
U.S. patent application No. 60/542,410, filed Feb. 6, 2004.

### BACKGROUND OF THE INVENTION

1. Technical Field of the Invention

This invention relates in general to integrated circuits, and more particularly to a method and apparatus of parallel testing of identical circuit core functions embedded within integrated circuits.

2. Description of the Related Art

An SOC design may consist of many types of embedded core functions such as DSPs, CPUs, memories, and various other types. In some instances the SOC may include multiple cores of the same type to allow each core to function independently to achieve greater SOC performance. If the cores are identical, they will share a common design for test (DFT) architecture and test (stimulus and response) pattern set. The present invention provides an improved core DFT architecture that enables cores of identical types to be more receptive to parallel testing.

FIG. 1 illustrates one simplified aspect of the DFT architecture described in referenced U.S. Pat. No. 6,560,734. The DFT architecture of U.S. Pat. No. 6,560,734 introduces the concept of providing compare circuitry with each core such that during test the response output from the core may be locally compared with expected data input to the SOC from an external tester.

The dotted box 100 around the core 110 and compare circuitry 108 of FIG. 1 is used to indicate that the compare circuitry and core, in one preferred embodiment described in U.S. Pat. No. 6,560,734, are connected together in the SOC to form a well defined circuit arrangement. In this embodiment, the compare circuitry 108 is dedicated for use in testing core 110 and accompanies core 110 when core 110 is used within an SOC. Circuit arrangement 100 is realized whenever testing of core 110 is required. The simplified diagram of FIG. 1 of the present invention relates to the drawing figures of U.S. Pat. No. 6,560,734 as follows.

The Expected Data bus 102 of FIG. 1 of the present invention is the bus that inputs expected data from the tester to compare circuitry 108. In U.S. Pat. No. 6,560,734 this bus is the IOB bus of FIG. 1 which is input to the SOC 100 from the tester, via the FIO, and input to comparator 806 of FIG. 8A.

The Stimulus Data bus 104 of FIG. 1 of the present invention is the bus that inputs test stimulus from the tester to the core under test 110. In U.S. Pat. No. 6,560,734 this bus is the IB bus of FIG. 1 which is input to the SOC 100 from the tester, via the FIO, and input (I) to the core under test 120 via test port 105.

The Response Data bus 106 of FIG. 1 of the present invention is the bus that inputs test response from the core under test 110 to compare circuitry 108. In U.S. Pat. No. 6,560,734 this bus is the output (O) bus from the core under test 120 of FIG. 1 which is input to comparator 806 of FIG. 8A.

The Pass/Fail output 112 of FIG. 1 of the present invention is an output from the compare circuitry 108 which indicates pass or fail test results. In U.S. Pat. No. 6,560,734 this output is from the pass/fail flag circuitry 815 which is associated with comparator 806 of FIG. 8A. Compare circuitry 108 of FIG. 1 of the present invention comprises pass/fail flag circuitry similar to that of circuitry 815.

During test, a tester inputs stimulus and expected data to circuit arrangement 100 of FIG. 1. The compare circuitry 108 matches the response output from the core 110 with the expected data from the tester. A signal occurs on the pass/fail output whenever a mismatch occurs between the expected and response data to notify the tester of the failure. Multiple circuit arrangements 100, each with identical cores 110, may be tested in parallel by simultaneously inputting the same test pattern stimulus and expected data to all circuit arrangements 100 and monitoring the pass/fail output from all circuit arrangements 100.

The individual pass/fail outputs from the circuit arrangements 100 can be wired OR together to allow the tester to receive a single pass/fail output from the SOC during test. Control for the inputting is described in referenced U.S. Pat. No. 6,560,734. Pass/Fail flag memories in compare circuit 108, that store the result of individual response failures, can be read by the tester following the test to pinpoint which response signal or signals from core 110 failed. From this description it is seen that U.S. Pat. No. 6,560,734 provides a DFT architecture that allow multiple identical cores to be tested in parallel.

FIG. 2 illustrates one simplified aspect of the DFT architecture described in U.S. Pat. No. 6,717,429. The DFT architecture of that application introduces the concept of providing compare and mask circuitry 208 that is selectively connectable to one or more cores 216-218 such that during test the response output 222 from the connected core may either be locally compared with expected data 212 input from a tester or masked from being compared by the mask data 214 input from the tester.

In U.S. Pat. No. 6,717,429, the expected data 212 and mask data 214 was encoded, for one reason, to allow reducing the number of test input connections between the tester and SOC. A decoder circuit 220 in the SOC was used to extract the compare and mask data from each input on the encoded data bus 202 so that separate compare data 212 and mask data 214 are available for input to the compare and mask circuitry 208 during test. In present FIG. 2 is it seen that the cores 216-218 share use of the compare and mask circuitry 208. For example, core 216 may use the compare and mask circuitry 208 during its test, followed by core 218 reusing the compare and mask circuitry 208 during its test. The simplified diagram of FIG. 2 of the present invention relates to drawing figures of U.S. Pat. No. 6,717,429 as follows.

The Expected Data bus 212 of FIG. 2 of the present invention is the bus that inputs expected data from the tester to compare and mask circuitry 208. In U.S. Pat. No. 6,717,429 this bus is the EXP bus of FIG. 7A which is input to the SOC 1801 of FIG. 18A from the tester and input to comparator 702 and mask 703 circuitry of FIG. 7A.

The Stimulus Data busses 204 and 206 of FIG. 2 of the present invention are the buses that input test stimulus from the tester to the selected core under test 216, 218. In U.S. Pat. No. 6,717,429 these buses exist on bus 1810 of FIG. 18A which are input to the SOC 100 from the tester and input to the selected core 1805-1807 under test.

The Response Data bus 222 of FIG. 2 of the present invention is the bus that inputs test response from the selected core under test 216 or 218, via selector 224, to the compare and mask circuitry 208. In U.S. Pat. No. 6,717,429 this bus is the output of multiplexer 1816 of FIG. 18B which is input to the comparator 702 and mask 703 circuitry of FIG. 7A. Multiplexer 1816 of U.S. Pat. No. 6,717,429 is the selector 224 of FIG. 1 of the present invention.

The Pass/Fail output 210 of FIG. 2 of the present invention is an output from the compare and mask circuitry 208 which indicates pass or fail test results. In U.S. Pat. No. 6,717,429 this pass/fail output is from the pass/fail scan memory circuitry 704 of FIG. 13A which is associated with comparator 702 and mask 703 circuitry of FIG. 7A. As shown in FIG. 13A, the pass/fail output is preferably designed to allow wire OR' ing multiple pass/fail outputs together. Compare circuitry 208 of FIG. 1 of the present invention comprises similar pass/fail flag circuitry.

During test, a tester inputs stimulus 204-206 and encoded data 202 to circuit 200 of FIG. 2. Control for the inputting is described in U.S. Pat. No. 6,717,429. As previously mentioned, the expected data 212 and mask data 214 are extracted from the encoded data 202, by decoder 220, to provide separate expected and mask data input to compare and mask circuitry 208. The compare and mask circuitry operates to either compare the response output from the selected core 216-218 with the expected data or to mask the compare operation. The mask data controls whether or not to mask compare operations. A signal occurs on the pass/fail output 210 whenever a mismatch occurs between the expected and response data to notify the tester of the failure. Pass/Fail flags in compare circuit 208 store individual response signal failures to allow the tester to read them out at the end of test to determine which response signal or signals failed. From this description it is seen that U.S. Pat. No. 6,717,429 provides a DFT architecture that allows any number of cores 216-218 in an SOC to be individually selected and tested.

FIG. 3 illustrates one simplified aspect of the DFT architecture described in patent application Ser. No. 10/301,898. The DFT architecture of application Ser. No. 10/301,898 is identical to the DFT architecture of U.S. Pat. No. 6,717,429 with the one exception that application Ser. No. 10/301,898 foregoes the use of the encoded data input and associated decoder circuit 220 and uses instead separate expected data 302 and mask data 304 bus inputs from the tester. Other that this one exception, the circuit 300 operates to test cores 216-218 that same way as described in circuit 200 of FIG. 2.

### SUMMARY OF THE INVENTION

In accordance with the present invention, a core DFT architecture is provided which improves upon the referenced prior art in enabling simultaneous testing of identical cores embedded in SOCs. The improvement is based on providing each identical core with its own dedicated compare and mask circuitry for use during testing.

### BRIEF DESCRIPTION OF THE DRAWINGS

FIG. 1 illustrates one example embodiment of a core DFT architecture as described in U.S. Pat. No. 6,560,734.

FIG. 2 illustrates one example embodiment of a core DFT architecture as described in U.S. Pat. No. 6,717,429.

FIG. 3 illustrates one example embodiment of a core DFT architecture as described in application Ser. No. 10/301,898.

FIG. 4 illustrates one example embodiment of a core DFT architecture according to the present invention.

FIG. 5 illustrates one example embodiment of a plurality of FIG. 4 core DFT architectures configured for simultaneous testing within an SOC according to the present invention.

FIG. 6 illustrates one example embodiment of a plurality of SOC die or packaged ICs being simultaneously tested according to the present invention.

### DETAILED DESCRIPTION OF THE INVENTION

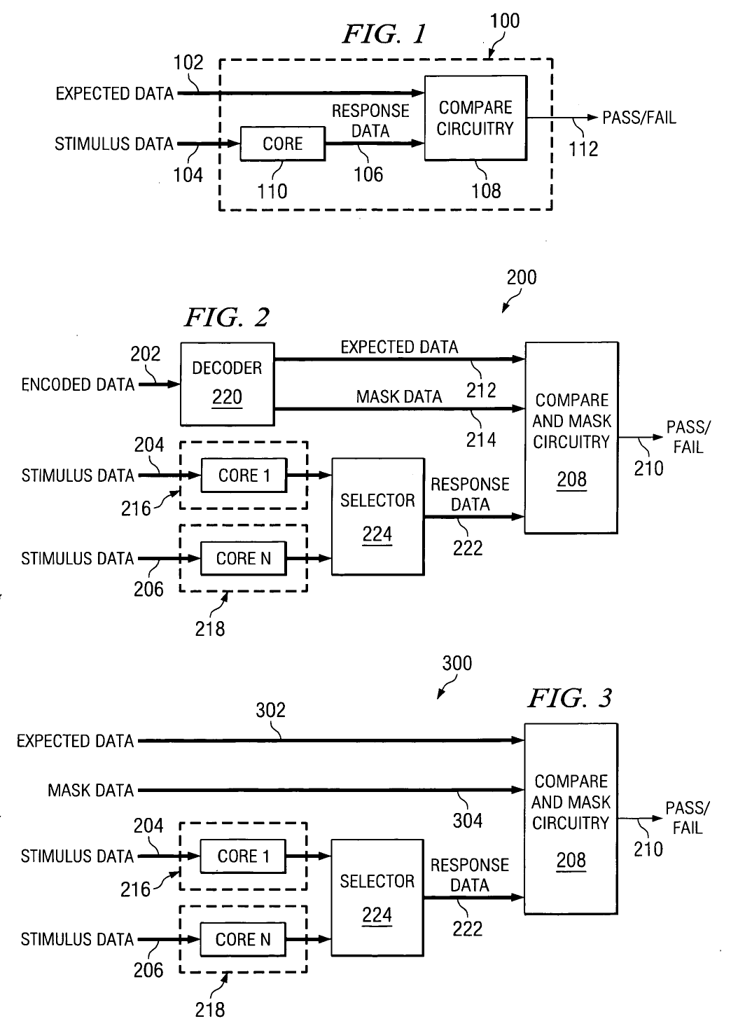

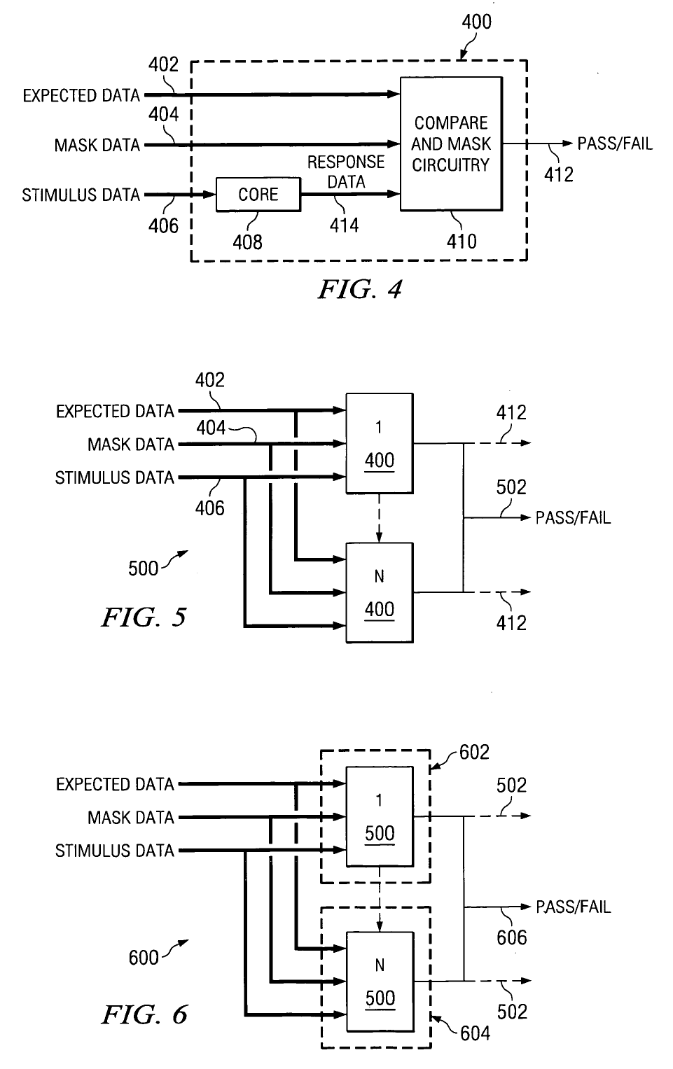

FIG. 4 illustrates a preferred embodiment of a circuit arrangement 400 for testing an individual core according to the present invention. In FIG. 4, core 408 and compare and mask circuitry 410 form a well defined circuit arrangement 400 indicated by dotted line. Circuit arrangement 400 is realized whenever testing of core 408 is required. The compare and mask circuitry 410 is dedicated for use in testing core 408 and accompanies core 408 when core 408 is used within an SOC. The testing of core 408 is similar to the testing of core 110 of FIG. 1 with the exception that compare and mask circuitry 410 is used in testing core 408 as opposed to using only compare circuitry 108 to test core 110 in FIG. 1. Using compare and mask circuitry 410 is an improvement over using only compare circuitry 108 since it allows for selectively masking unknown or don't care response outputs from the core 408 during test.

During test, a tester inputs stimulus data 406, mask data 404, and expected data 402 to circuit 400. Control for the inputting is described in referenced U.S. Pat. No. 6,560,734, U.S. Pat. No. 6,717,429 and application Ser. No. 10/301,898. The compare and mask circuitry 410 operates to either compare the response output 414 from core 408 with the expected data or to mask the compare operation. The mask data controls whether or not to mask compare operations. A signal occurs on the pass/fail output 412 whenever a mismatch occurs between the expected and response data to notify the tester of the failure. Pass/Fail flags in compare circuit 410 store individual response signal failures to allow the tester to read them out at the end of test to determine which response signal or signals failed. From this description it is seen that circuit arrangement 400 differs from the prior art circuit arrangements 100, 200, and 300 in the following ways.

Circuit arrangement 400 differs from circuit arrangement 100 in that circuit arrangement 400 includes compare and mask circuitry 410 instead of just compare circuitry 108.

Circuit arrangement 400 differs from circuit arrangement 200 and 300 in that circuit 400 dedicates the compare and mask circuitry 410 for the testing of only core 408, not for testing other cores.

FIG. 5 illustrates a preferred embodiment of a circuit arrangement 500 for parallel testing a plurality of identical circuit arrangements 400 embedded within an SOC according to the present invention. In FIG. 5, a plurality of circuit arrangements 400 are configured, during test mode, such that each are connected to receive input from a common expected data bus 402, a common mask data bus 404, and a common stimulus data bus 406 from a tester connected to the SOC. The circuit arrangements 400 are also configured to output their pass/fail outputs to the tester. As seen in FIG. 5, the pass/fail outputs may be output to the tester either as the individual pass/fail outputs 412 from each circuit arrangement 400 or as a wired OR output 502 of all the individual pass/fail outputs 412.

During test, the tester inputs stimulus data 406, mask data 404, and expected data 402 to the plurality of circuit arrangements 400. Control for the inputting is described in referenced U.S. Pat. No. 6,560,734, U.S. Pat. No. 6,717,429 and application Ser. No. 10/301,898. The compare and mask circuitry 410 of each circuit arrangement 400 operates simultaneously to either compare the response output 414 from the core 408 of each circuit arrangement 400 with the expected data, or to mask the compare operation. The mask data controls whether or not to mask compare operations. The pass/fail outputs 412 from each circuit arrangement 400 signal the tester whenever a mismatch occurs between the expected and response data. Pass/Fail flags in compare circuit 410 of each circuit arrangement store individual response signal failures to allow the tester to read them out at the end of test to determine which response signal or signals of each circuit arrangement 400 failed.

From this description it is seen that circuit arrangement 500 allows for testing a plurality of circuit arrangements 400 in parallel. The test time of testing a plurality of circuit arrangements 400 is the same as the test time of testing a single circuit arrangement 400. Thus significant test time reduction of the SOC containing circuit arrangement(s) 500 can be realized, along with a corresponding reduction in cost of the SOC.

FIG. 6 illustrates a preferred embodiment of a circuit arrangement 600 for parallel testing of a plurality of identical SOCs 602-604. The SOCs 602-604 may be tested at any SOC manufacturing stage such as SOC die on wafer, singulated SOC die, SOC die mounted on a lead frame, or completely packaged SOCs. Each SOC 602-604 contains an identical embedded circuit arrangement 500 of identical cores 400 as previously described in regard to FIGS. 5 and 4 respectively.

In FIG. 6, the plurality of circuit arrangements 500 in each SOC 602-604 are configured during test mode such that each are connected to receive input from a common expected data bus 402, a common mask data bus 404, and a common stimulus data bus 406 from a tester connected to the SOCs 602-604. The circuit arrangements 500 are also configured to output their pass/fail outputs to the tester either as the individual wired OR pass/fail outputs 502 from each circuit arrangement 500, or as a wired OR output 606 of all the individual pass/fail outputs 502.

During test, the tester inputs stimulus data 406, mask data 404, and expected data 402 to the plurality of circuit arrangements 500 embedded in each SOC 602-604. Control for the inputting is described in referenced U.S. Pat. No. 6,560,734, U.S. Pat. No. 6,717,429 and application Ser. No. 10/301,898. The compare and mask circuitry 410 of each circuit arrangement 400 in circuit arrangements 500 operates simultaneously to either compare the response output 414 from the core 408 of each circuit arrangement 400 with the expected data, or to mask the compare operation. The pass/fail outputs 412 from each circuit arrangement 400 in circuit arrangement 500 signal the tester whenever a mismatch occurs between the expected and response data. Pass/Fail flags in compare circuit 410 of each circuit arrangement 400 store individual response signal failures to allow the tester to read them out at the end of test to determine which response signal or signals of each circuit arrangement 400 in circuit arrangement 500 failed.

From this description it is seen that circuit arrangement 600 allows for testing a plurality of SOCs 602-604 in parallel. The test time of testing a plurality of SOCs 602-604 is the same as the test time of testing a single SOC 602. Thus significant SOC test time reduction can be realized, along with a corresponding reduction in SOC cost.

It should be noted that the referenced U.S. Pat. No. 6,560,734 and U.S. Pat. No. 6,717,429 have previously described parallel testing of die and packaged ICs similar to that shown in FIG. 6. The improvement of FIG. 6 over these references is that the parallel testing of FIG. 6 is improved through the use of identical cores each having dedicated compare and mask circuitry as described in regard to FIG. 4.

Although the present invention has been described in detail, it should be understood that various changes, substitutions and alterations can be made herein without departing from the spirit and scope of the invention as defined by the appended claims.

1. A core test arrangement for use within an integrated circuit comprising,
a core to be tested having inputs for receiving test stimulus data from a tester and outputs for outputting test response data, and;
test compare and mask circuitry dedicated for testing the core, said compare and mask circuitry having a first input group for receiving the core response data outputs, a second input group for receiving expected data from the tester, and a third input group for receiving mask data from the tester.

2. The integrated circuit of claim 1 wherein a plurality of identical core test arrangements exist within the integrated circuit, each identical core test arrangement sharing a common connection to the stimulus data input from the tester, a common connection to the expected data input from the tester, and a common connection to the mask data input from the tester.
